(19) United States
(12) Patent Application Publication
(10) Pub. No.: US 2002/0048942 A1
(43) Pub. Date: Apr. 25, 2002

(54) METHOD OF MANUFACTURING SEMICONDUCTOR DEVICE WITH TWO STEP FORMATION OF CONTACT HOLE

(76) Inventor: YOSHIHIRO YAMAGUCHI, NAGASAKI (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/082,918

(22) Filed: May 21, 1998

(30) Foreign Application Priority Data
May 21, 1997 (JP) P09-130717

(51) Int. Cl. H01L 21/4763; H01L 21/44

(52) U.S. Cl. 438/672; 438/618; 438/622; 438/669

(57) ABSTRACT

In a semiconductor device and a method of manufacturing the same, a layer insulating film is formed on a first wiring layer, and large-diameter contact holes are patterned on the layer insulating film. The large-diameter contact holes are etched until a predetermined depth to open the large-diameter contact holes until some midpoint of the layer insulating film. A second wiring layer is formed on the layer insulating film while containing the large-diameter contact holes, and then etched back to remove the second wiring layer material at the bottom portions of the large-diameter contact holes. Contact holes are opened from the bottom portions of the large-diameter contact holes to the layer insulating film by using the second wiring layer as a mask to form contact holes intercommunicating from the upper surface of the second wiring layer to the upper surface of the first wiring layer, and blanket metal is formed while covering the contact holes and the second wiring layer. The upper surface of the blanket metal is etched to form metal plugs, and the second wiring layer is patterned.

### BACKGROUND OF THE INVENTION

The present invention relates to a semiconductor device and a method of manufacturing the semiconductor device, and particularly to contact holes for the electrical connection between wiring layers in a semiconductor device having a multilayered wiring structure.

In connection to the high integration design of semiconductor devices, the wiring technique has been increasingly advanced to achieve a further micro and multilayer structure, and the multilayer wiring technique has been increasingly placed at a further important position in the process of manufacturing semiconductor integrated circuits. For example, in a transistor having such a microstructure that the gate length is equal to 0.35 μm or less, the width of a first wire which is connected to the transistor is also reduced, and at the same time the pitch between wires is small. Further, a second wire which is connected to the first wire is also reduced in width to have a small wiring width, and also it must be manufactured by using a high wiring pattern matching technique so that the wiring pitch can be matched with the narrow wiring pitch of the first wiring.

As described above, the manufacturing process of the semiconductor devices has required further more rigorous device management and process management.

FIGS. 1A to 1E are cross-sectional views showing the main part of the manufacturing process of a conventional semiconductor device which are arranged in the process order, and FIG. 2 is a flowchart of the manufacturing process.

As shown in FIG. 1A, a pattern of a first wiring layer 101 is formed on a semiconductor wafer 100 on which an element separating area and a transistor (not shown) are formed. A layer insulating film 102 of an oxide film is formed on the first wiring layer 101, and then subjected to a flattening treatment (step S1 in FIG. 2). Further, a resist 103 is coated on the layer insulating film 102, and then subjected to a patterning treatment for contact holes (step S2). Thereafter, the layer insulating film 102 is etched by using the resist 103 as a mask.

By the etching of the layer insulating film 102, contact holes 104 are formed in the layer insulating film (step S3) as shown in FIG. 1B. Thereafter, the resist 103 is removed (step S4), and a metal plug adhesive layer (not shown) which is composed of a thin film of titan nitride (TiN) or the like is formed in each of the contact holes 104 by the sputtering method, the metal CVD method or the like.

Subsequently, as shown in FIG. 1C, blanket metal 105 of tungsten (W) is formed by the metal CVD method to fill the contact holes 104 with metal (step S5).

Subsequently, as shown in FIG. 1D, undesired blanket metal 105 on the layer insulating film 102 is etched back to leave only the metal in the contact holes 104, thereby forming metal plugs 106 (step S6). At this time, since the over-etching is performed to completely remove the blanket metal on the layer insulating film 102, a recess 109 (plug loss b) is formed at the upper portion of each metal plug 106 in the contact hole 104.

Subsequently, a titan (Ti) layer (not shown) and a TiN layer (not shown) are formed, and then as shown in FIG. 1E, a second wiring layer 107 (laminate film) which is formed of aluminum alloy, for example, Al—Si, Al—Cu, Al—Si—Cu or the like is continuously formed by the sputtering method (step S7).

Subsequently, the second wiring layer 107 is subjected to a patterning treatment, and etched by a photolithography technique to form a second wiring pattern (step S8). As described above, the second wiring pattern which is electrically conducted through the metal plugs 106 to the first wiring pattern is formed on the first wiring pattern.

However, the conventional semiconductor device as described above has the following problems due to the reduction of the device.

A first problem resides in increase of the contact resistance of the contact face between the metal plug and the wiring layer. The contact face between the metal plug 106 and the second wiring layer 107 (FIGS. 1A to 1E) is conventionally designed as a circular open face 108 as shown in FIG. 3. Accordingly, the contact area S1 thereof is expressed as follows: S1=πD²/4. Accordingly, when the opening diameter of the contact hole is reduced from 0.5 μm to 0.4 μm by 0.1 μm, the contact resistance is increased at 1.65 times. Further, as the contact diameter is reduced, the dispersion of the contact size in the photolithography process becomes larger, and the contact resistance is also dispersed, so that stable characteristics cannot be obtained.

A second problem resides in that the margin of the positioning (alignment) of the contact holes in the photolithography process is reduced. Therefore, when contact holes are formed in the layer insulating film 102 on the first wiring layer 101 as show in FIGS. 4A and 4B, an opening pattern 103a of the resist 103 and the first wiring layer 101 are positionally displaced from each other. When an etching treatment is performed in this positionally displaced state, the contact holes 104 are displaced out of the first wiring layer 101 as shown in FIG. 4B. The positional displacement of the contact holes as described above causes a connection failure or increases the connection resistance. Particularly in the case of a multilayer wiring of three or more layers, the alignment is displaced between layers, and reliability of the connection is lowered.

### SUMMARY OF THE INVENTION

The present invention has been implemented to overcome the above problems, and has an object to provide a semiconductor device and a manufacturing method thereof which can ensure a sufficient contact area to suppress the contact resistance to a stable and sufficient small value, and increase the margin of the positioning of contacts to surely connect wiring layers to each other, thereby obtaining a connection structure having high connection reliability.

In order to attain the above object, according to a first aspect of the present invention, a semiconductor device having such a multilayered wiring structure that a second wiring layer is provided on a first wiring layer through a layer insulating layer, the first and second wiring layers being electrically connected to each other by metal plugs of metal material which are filled in contact holes formed between the first and second wiring layers, is characterized in that each of the metal plugs is formed so as to extend to the upper surface of the second wiring layer, a contact hole having a large diameter is formed around each metal plug so as to extend from the upper surface of the layer insulating film to a predetermined depth, and the metal material of the second wiring layer serving as the top layer is filled in the gap between the large-diameter contact hole and the metal plug.

According to a second aspect of the present invention, a method of manufacturing the above semiconductor device, is characterized by comprising: (1) a step of forming a layer insulating film on a first wiring layer, (2) a step of performing a patterning treatment on the large-diameter contact hole on the layer insulating film, (3) a step of etching the large-diameter contact hole until a predetermined depth to open the layer insulating until some midpoint thereof, (4) a step of forming a second wiring layer containing the partway opened large-diameter contact hole on the layer insulating film, (5) a step of etching back the second wiring layer to remove the material of the second wiring layer at the bottom portion of the large-diameter contact hole, (6) a step of opening a contact hole from the bottom portion of the large-diameter contact hole to the layer insulating film to form a contact hole which intercommunicates from the upper surface of the second wiring layer to the upper surface of the first wiring layer, (7) a step of forming blanket metal which covers the contact hole and the second wiring layer, (8) a step of etching the upper surface of the blanket metal to form a metal plug, and (9) a step of patterning the second wiring layer.

According to the present invention, the contact hole is opened not only in the layer insulating film, but also in the second wiring layer which is the upper layer on the layer insulating film, and the metal plug is formed so as to extend to the upper surface of the second wiring layer. Therefore, the contact face between the second wiring layer and the metal plug corresponds to the side surface of the metal plug, and the contact area can be set to a large value. That is, representing the diameter of the metal plug by D and representing the film thickness of the second wiring layer by Th, the contact area S2 is expressed as follows: S2=πD·Th. Further, as described with reference to FIG. 3, the contact area S1 of the conventional metal plug is expressed as follows: S1=πD²/4. Accordingly, in order to satisfy S1<S2,

D/4<Th (1)

That is, when the film thickness of the second wiring layer is larger than ¼ of the contact diameter, the contact area is larger than that of the conventional structure, and the contact resistance can be reduced.

General design values of the multilayered structure based on the recent metal plug connection are as follows. The contact size is equal to 1 μm or less, ordinarily about 0.5 μm, or a smaller value. Further, with respect to the second wiring layer, the film thickness thereof is equal to about 0.5 to 1.0 μm. Actually, the material of the second wiring at the large-diameter contact portion is further added to the contact face, and thus the equation (1) is sufficiently satisfied.

In the above structure, the large-diameter contact hole continuous to the second wiring layer is formed, so that the margin of the positioning is increased and the metal plug can be matched with the wiring pattern of the narrow first wiring layer with high precision, thereby achieving high-reliability connections. This point will be described in more detail below.

The present invention pays attention to the step coverage characteristic of the sputtering method which is used to form wiring layers.

The step coverage characteristic is shown in FIG. 5A. As shown in FIG. 5B, representing the film thickness of the second wiring layer 107 by Th; the film thickness of the side surface in the contact hole, Ts; and the film thickness of the bottom surface, Tb, the coating rate of the bottom portion is represented by Tb/Th×100%, and the coating rate of the side surface is represented by Ts/Th×100%. Further, the aspect ratio is represented by b/a. As shown in FIG. 5A, when the aspect ratio of the step of the back layer (contact hole) is increased to 0.7 or more, the easiness of the coating of the sputtered film is rapidly lowered, and the film thickness is reduced to 10% or less of the film thickness of the wiring layer at the side wall portion of the contact hole, and 20% or less at the bottom portion of the contact hole.

As described above, since the film thickness of the coating inside the contact hole is determined substantially in accordance with the aspect ratio, and the diameter of the contact hole can be increased to a desired size by using the above characteristic and forming the wiring layer so that the opening diameter of the contact hole is increased by the amount corresponding to the film thickness of the side wall of the sputtered wiring film. That is, a large-diameter contact hole is beforehand formed, and a wiring film is coated at a predetermined thickness on the inner wall surface of the large-diameter contact hole by the sputtering method to form a contact hole having a predetermined diameter, whereby a contact hole having a fine diameter can be formed with high precision. In this case, the open margin of the film thickness of the side wall is dependent on the opening depth of the contact hole, and thus a contact hole having a predetermined diameter can be formed by varying the opening depth, that is, varying the aspect ratio.

Further, the overall surface of the second wiring layer is etched back to remove the wiring layer of the contact bottom portion by a metal etching device, the contact is patterned by the wiring layer, and the layer insulating film is etched with the wiring layer pattern as a mask by an oxide film etching device so that only the oxide film (insulation film) which is selectively contact-opened under a high selection ratio etching condition reaches the first wiring layer, whereby the contact can be opened with self-alignment, and there occurs no problem in positional displacement. In this case, if the aspect ratio of the large-diameter contact hole is set to 1.0 or more, the second wiring layer formed at the bottom portion of the contact is reduced in thickness, and the etch-back amount of the wiring layer can be reduced by the amount corresponding to the reduction of the film thickness of the second wiring layer.

### BRIEF DESCRIPTION OF THE DRAWINGS

FIGS. 1A to 1E are cross-sectional views showing a process of manufacturing a conventional semiconductor device;

FIG. 2 is a flowchart showing the manufacturing process of FIGS. 1A to 1E;

FIG. 3 is a diagram showing the contact area of a conventional metal plug;

FIGS. 4A and 4B are diagrams showing a problem of the conventional semiconductor device;

FIGS. 5A and 5B are diagrams showing the coating characteristic at a step portion of sputtering coating;

FIGS. 6A to 6D are cross-sectional views showing a process of manufacturing a semiconductor device according to the present invention;

FIGS. 7E to 7G are cross-sectional views showing a subsequent process to the process shown in FIGS. 6A to 6D;

FIG. 8 is a top view showing the semiconductor device of the present invention;

FIG. 9 is a top view showing the semiconductor device of the present invention; and

FIG. 10 is a flowchart showing the manufacturing processes shown in FIGS. 6A to 6D and FIGS. 7E to 7G.

### DETAILED DESCRIPTION OF THE PREFERRED EMBODIMENT

A preferred embodiment according to the present invention will be described with reference to the accompanying drawings.

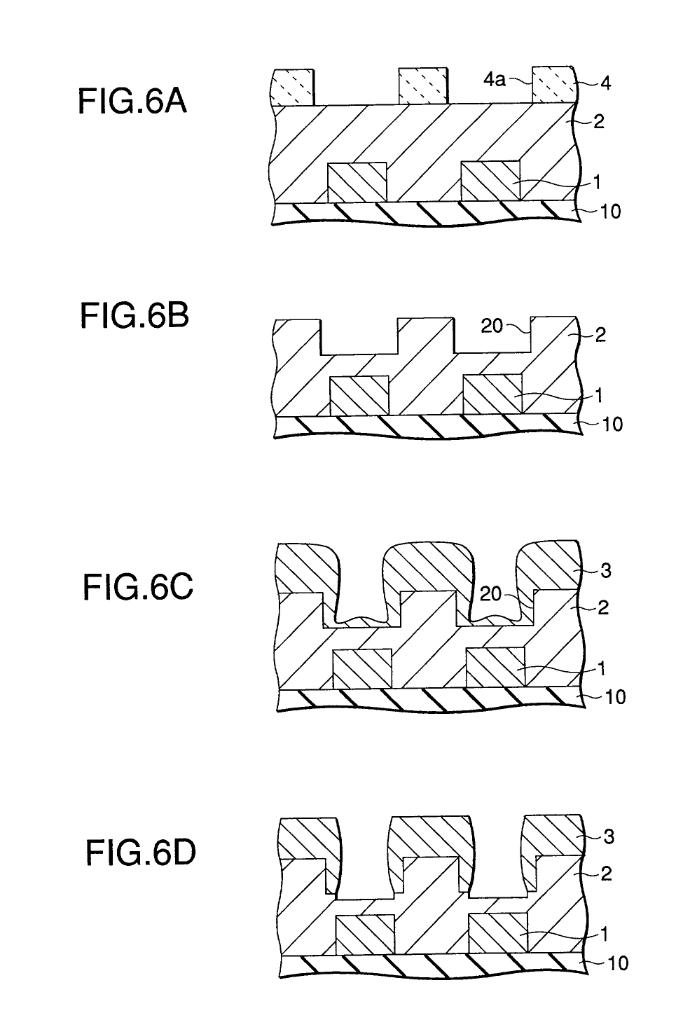

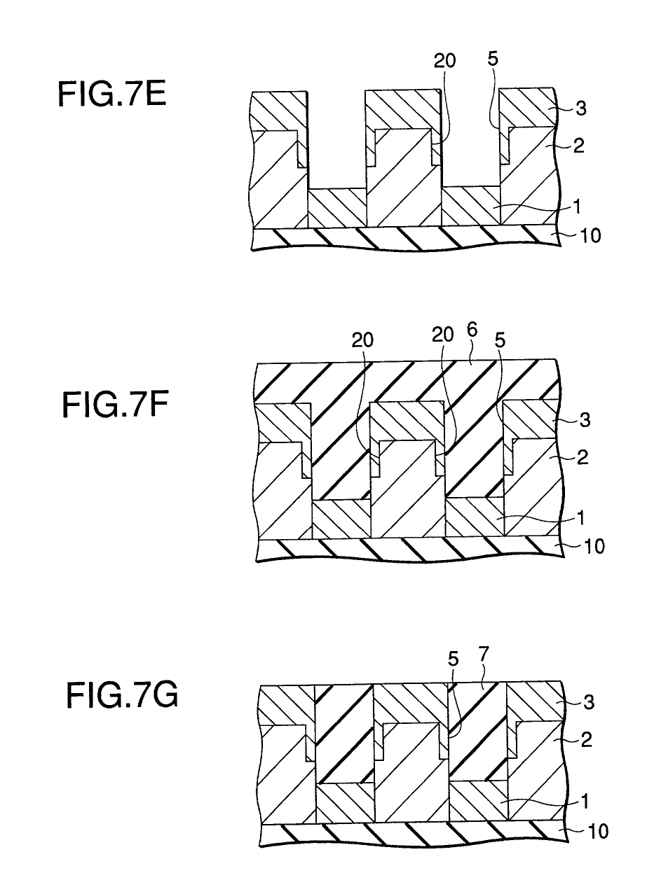

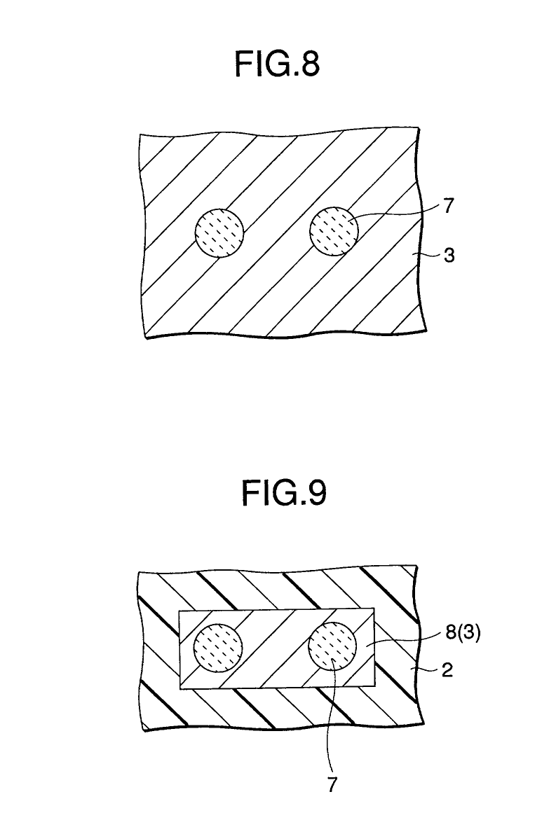

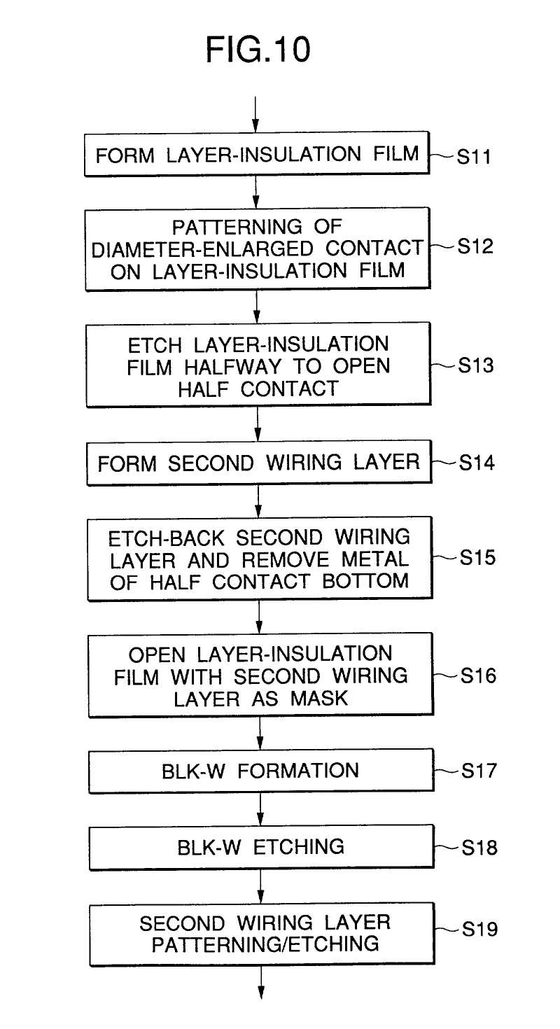

FIGS. 6A to 6D and FIGS. 7E to 7G are cross-sectional views showing a process of manufacturing a semiconductor device according to an embodiment of the present invention, FIG. 8 is a top view of FIG. 7G, FIG. 9 is a top view of the subsequent process, and FIG. 10 is a flowchart of the manufacturing process.

As shown in FIG. 6A, a first wiring layer 1 is formed on a semiconductor wafer 10 having an element separation area and a transistor area (not shown) which are formed by a normal method. Further, a layer insulating film 2 formed of an oxide film is formed on the first wiring layer 1, and then subjected to a flattening treatment (step S11 of FIG. 10).

Subsequently, a resist 4 is coated on the layer insulating film 2 by a normal method such as a spin coat method, and openings 4a are formed by the photolithography technique, thereby patterning large-diameter contact holes (step S12). Here, the opening pattern of the resist 4 is set so that the diameter of each opening 4a is larger than the final opening diameter 500 nm by 65 nm in radius in consideration of the side wall coating rate of 10% of the contact having the aspect ratio of 0.7 when the film thickness of the second wiring layer is equal to 650 nm, and thus each large-diameter contact hole thus formed have an opening diameter of 500 nm+65×2 nm=630 nm (0.63 μm).

Subsequently, as shown in FIG. 6B, large-diameter contact holes 20 are formed in the layer insulating film 2 by using a normal oxide film etching device. The large-diameter contact hole 20 is formed as a half contact which extends to some midpoint of the layer insulating film 2 before it reaches the first wiring layer 1 (step S13). The depth of the contact at this time is set to such a value that the side wall coating rate of the contact of the second wiring layer which will be afterwards formed is equal to 10%. That is, since the opening diameter a is equal to 0.63 μm and the aspect ratio is equal to 0.7, b/0.63=0.7, that is, the depth b is equal to about 0.44 μm. After the etching is finished, the resist 4 is removed by ashing, and then the result is subjected to a cleaning treatment using washing liquid (FIG. 6B).

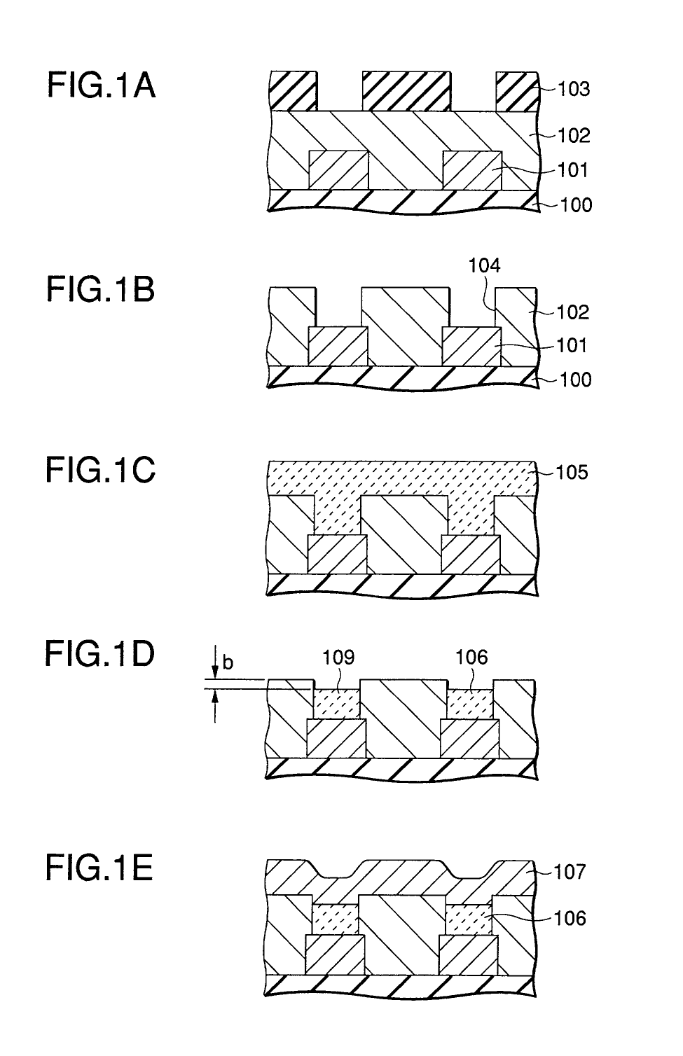

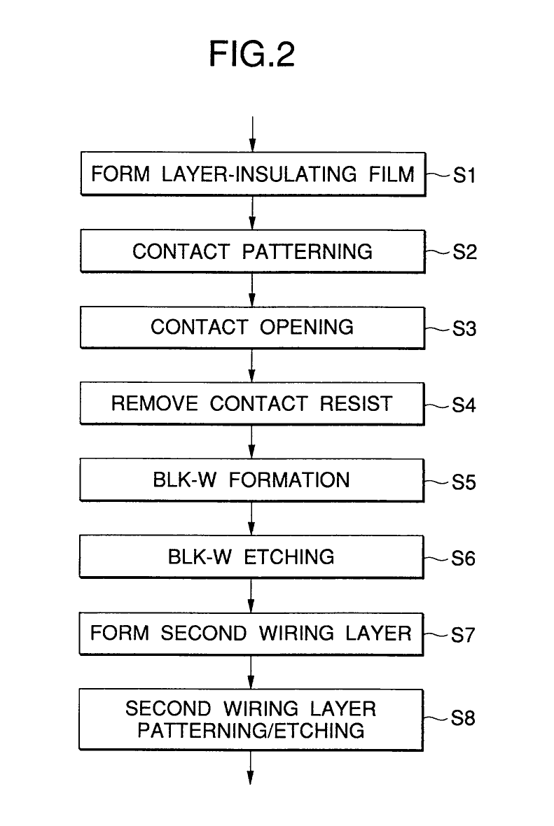

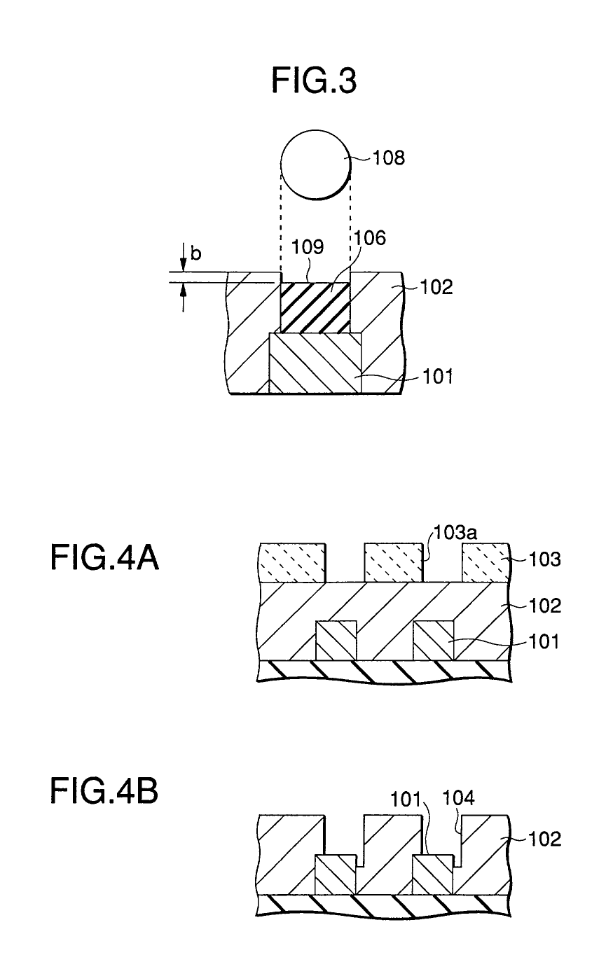

Subsequently, as shown in FIG. 1C, a laminate film formed of titan (Ti), TiN and aluminum alloy such as Al—Si, Al—Cu, Al—Si—Cu or the like is continuously formed under vacuum by using a multi-chamber type DC magnetron sputtering device to form a second wiring layer 3 (step S14). In this case, the laminate film is formed in the order: Ti 100 nm (lowest layer)/TiN 20 nm/Ti 10 nm/Al-0.5%Cu 500 nm/TiN 20 nm, and the total film thickness of the laminate film is set to 650 nm. The film forming temperature in the sputtering process is set to 200° C. under which the coating shape is most stable.

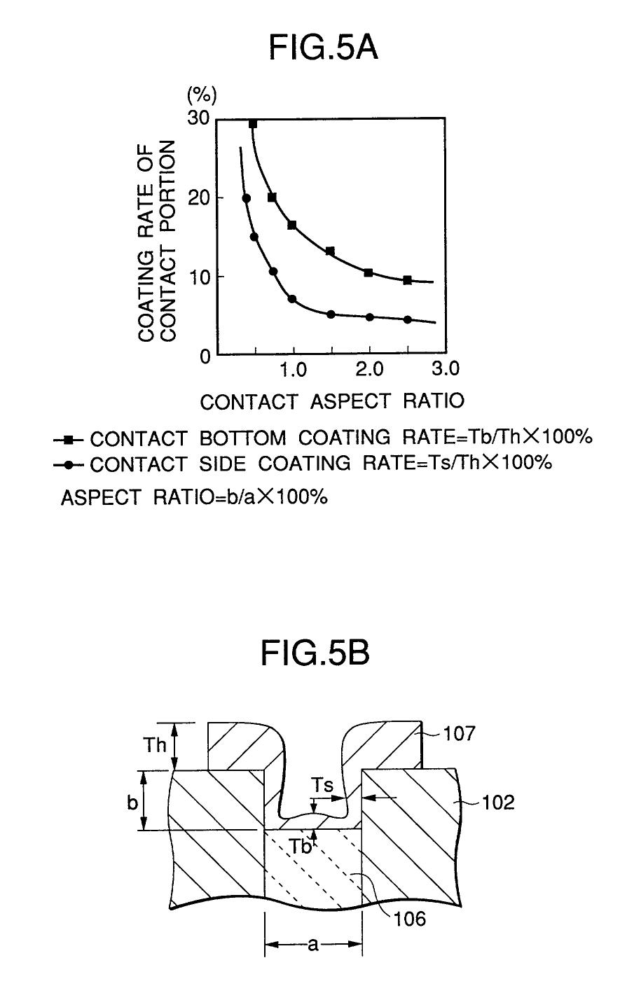

Subsequently, as shown in FIG. 6D, the second wiring layer 3 is etched back anisotropically, that is, in the vertical direction over the whole surface of the wafer by reactive ion etching (RIE) using a metal etching device to remove the film of the second wiring layer 3 at the bottom portion of the contact, thereby exposing the layer insulating film 2 (step S15). The etch-back amount at this time is set so that the second wiring metal (the film thickness of the second wiring layer 3) at the bottom portion of the half contact is perfectly removed. That is, as is apparent from the coating characteristic graph of FIG. 5, the film thickness coating rate of the contact bottom portion is equal to about 20% at the aspect ratio of 0.7. Accordingly, if the film thickness of the second wiring layer is equal to 650 nm, 650 nm×20%=130 nm, and thus the etch-back amount is set to the sum of 130 nm and an over-etch amount (20 nm), that is, 150 nm.

Subsequently, as shown in FIG. 7E, the layer insulating film 2 exposed at the bottom portion of the half contact is anisotropically etched with the second wiring layer 3 as a mask by the reactive ion etching using the oxide film etching device to form contact holes 5 (step S16). At this time, the film of the second wiring layer 3 is formed on the side wall of the large-diameter contact hole (half contact) 20. The etching selection ratio of the wiring layer and the insulating film is set to about 10, i.e., the condition is set so that the insulating film is perfectly removed without etching the wiring layer when the etching reaches the first wiring layer 1. Further, in this case, the second wiring layer is used as the mask, and thus the opening of the contact hole is positioned to the opening of the second wiring layer with self-alignment, and thus no positional displacement occurs between these openings.

Next, a metal plug adhesive layer (not shown) of TiN 20 nm is formed on the whole surface containing the inner surface of the contact hole 5 by a low-pressure long-distance sputtering method. Thereafter, as shown in FIG. 7F, blanket tungsten (BLK-W) 6 is formed at a thickness of 700 nm by the metal CVD method to fill the contact holes 5 with tungsten (step S17).

Subsequently, as shown in FIG. 7G, an undesired upper layer of BLK-W is etched back over the whole surface of the wafer by the metal etching device to leave tungsten only in the contact holes, thereby forming metal plugs 7 (step S18). At this time, if the etching is stopped when the surface of the second wiring layer 3 appears during the etch-back process of W, the upper surface of the second wiring layer 3 and the upper surfaces of the metal plugs 7 are located on the same plane because they are composed of metal and no over-etch is needed. At this time, as shown in FIG. 8, the metal plugs 7 are exposed from the surface of the second wiring layer 3, and they are brought into contact with the second wiring layer 3 at the side surfaces thereof.

Subsequently, as shown in FIG. 4, the second wiring layer 3 is patterned and etched to form a second wiring pattern 8 (step S19). As described above, there can be obtained such a contact structure that the metal plugs are filled in the contact holes which are opened until the upper surface of the second wiring layer through the large-diameter contact holes, the upper surface thereof is perfectly flattened and the metal plugs are brought into contact with the second wiring layer at the side surfaces thereof.

The above embodiment is directed to the two-layer wiring structure, however, the present invention may be applied to a multilayered wiring structure having three or more layers by successively applying the method of the above embodiment from the lower layer side.

As described above, according to the present invention, the metal plugs are formed until the upper surface of the wiring layer serving as the upper layer to connect the metal plugs to the upper wiring layer at the side surfaces of the metal plugs. Therefore, the contact area can be increased, and the reduction of the contact area of the contact hole due to the recent compact design of the semiconductor devices having the multilayered wiring structure can be prevented, and the contact resistance can be reduced, thereby obtaining devices having stable characteristics.

Further, the half contact having a larger diameter than the finally required contact diameter is formed, and the film thickness on the inner wall of the contact is controlled on the basis of the step coverage characteristic to obtain a desired opening diameter. Therefore, the margin corresponding to the difference between the permissible maximum opening diameter and the minimum opening diameter is increased, and the patterning precision and the workability can be enhanced. In addition, the margin of the positional displacement is increased, and thus the metal plugs and the wiring layer can be surely positioned to each other, so that the connection reliability is enhanced and the manufacturing yield can be enhanced.

What is claimed is:

1. A semiconductor device having such a multilayered wiring structure that a second wiring layer is provided on a first wiring layer through a layer insulating layer, the first and second wiring layers being electrically connected to each other by metal plugs of metal material which are filled in contact holes formed between the first and second wiring layers, characterized in that each of said metal plugs is formed so as to extend to the upper surface of said second wiring layer, a contact hole having a large diameter is formed around each metal plug so as to extend from the upper surface of said layer insulating film to a predetermined depth, and the metal material of said second wiring layer serving as the top layer is filled in the gap between said large-diameter contact hole and said metal plug.

2. A method of manufacturing a semiconductor device, comprising:
(1) a step of forming a layer insulating film on a first wiring layer;
(2) a step of performing a patterning treatment on a large-diameter contact hole on a layer insulating film;
(3) a step of etching the large-diameter contact hole until a predetermined depth to open the layer insulating until some midpoint thereof;
(4) a step of forming a second wiring layer containing the partway opened large-diameter contact hole on the layer insulating film;
(5) a step of etching back the second wiring layer to remove the material of the second wiring layer at the bottom portion of the large-diameter contact hole;
(6) a step of opening a contact hole from the bottom portion of the large-diameter contact hole to the layer insulating film to form a contact hole which intercommunicates from the upper surface of the second wiring layer to the upper surface of the first wiring layer;
(7) a step of forming blanket metal which covers the contact hole and the second wiring layer;
(8) a step of etching the upper surface of the blanket metal to form a metal plug; and
(9) a step of patterning the second wiring layer.

3. The semiconductor device manufacturing method as claimed in claim 2, wherein the opening diameter of the large-diameter contact hole corresponds to the side-wall coating film thickness of the second wiring layer formed in said contact hole.

4. The semiconductor device manufacturing method as claimed in claim 2, wherein said large-diameter contact hole is etched in such a depth that the aspect ratio thereof is equal to 0.7 or more.

5. The semiconductor device manufacturing method as claimed in claim 2, wherein said second wiring layer is formed by sputtering, and the opening diameter of the contact is controlled on the basis of a step coverage characteristic of the sputtering.
